(19) United States
(12) Patent Application Publication
(10) Pub. No.: US 2015/0177028 A1
(43) Pub. Date: Jun. 25, 2015

(54) SENSOR PACKAGE AND PORTABLE TERMINAL HAVING THE SAME

(71) Applicant: SAMSUNG ELECTRO-MECHANICS CO., LTD., Suwon-Si (KR)

(72) Inventors: Sun Kyu LEE, Suwon-Si (KR); Tae Kon KOO, Suwon-Si (KR); Tae Hoon KIM, Suwon-Si (KR); Kyu Hwan OH, Suwon-Si (KR); Seog Moon CHOI, Suwon-Si (KR)

(73) Assignee: SAMSUNG ELECTRO-MECHANICS CO., LTD., Suwon-Si (KR)

(21) Appl. No.: 14/295,963

(22) Filed: Jun. 4, 2014

(30) Foreign Application Priority Data
Dec. 24, 2013 (KR) 10-2013-0162207

(51) Int. Cl. G01D 11/24; H01L 35/00; H01L 23/495

(52) U.S. Cl. CPC G01D 11/245; H01L 23/495; H01L 35/00

(57) ABSTRACT

A sensor package may allow a fluid to flow smoothly to thus increase response characteristics. The sensor package may include: a terminal part; at least one electronic element electrically connected to the terminal part through a bonding wire; and a molded part encapsulating the bonding wire and the electronic element and including a sensing portion partially exposing the electronic element and at least one guide portion guiding an ambient fluid to the sensing portion.

### CROSS-REFERENCE TO RELATED APPLICATION

This application claims the benefit of Korean Patent Application No. 10-2013-0162207 filed on Dec. 24, 2013, with the Korean Intellectual Property Office, the disclosure of which is incorporated herein by reference.

### BACKGROUND

The present disclosure relates to a sensor package and a portable terminal having the same, and more particularly, to a sensor package allowing a fluid to flow smoothly to thus increase response characteristics, and a portable terminal having the same.

Recently, as electronic products such as cellular phones, notebook computers, and the like, have been miniaturized, while performances thereof have been required to be improved, internal components have also been reduced in volume. In this regard, while such internal components have been reduced in size, performances thereof have been required to be enhanced.

Under these circumstances, numerous products have been researched and developed in the field of sensors installed in portable terminals. Among such sensors, for example, a temperature-humidity sensor has recently been employed in portable terminals and has gained widespread interest and demand.

When a temperature-humidity sensor is employed in portable terminals such as smartphones, accuracy and response speeds thereof are critical factors, and thus, manufacturers developing temperature-humidity sensors have made great efforts to enhance accuracy and response speeds thereof.

However, related art sensor packages are installed in thin electronic elements such as portable terminals, making it difficult for ambient air to be introduced to a surface of a sensor. As a result, response characteristics of sensors are degraded.

Thus, a sensor package having enhanced response speeds and reliability in a temperature-humidity sensor and a mounting structure therefor are required.

### RELATED ART DOCUMENT

(Patent Document 1) U.S. Pat. No. 7,901,971

### SUMMARY

An aspect of the present disclosure may provide a sensor package having enhanced sensor response characteristics, and a portable terminal having the same.

According to an aspect of the present disclosure, a sensor package may include: a terminal part; at least one electronic element electrically connected to the terminal part through a bonding wire; and a molded part encapsulating the bonding wire and the electronic element and including a sensing portion partially exposing the electronic element and at least one guide portion guiding an ambient fluid to the sensing portion.

The sensing portion may have a through hole, and one surface of the electronic element may close one end of the through hole.

The sensing portion may have a cross-sectional area decreasing in a direction toward one end thereof.

The terminal part may be provided as a lead frame.

The bonding wire may be disposed to have a vertex positioned higher than the electronic element.

The at least one guide portion may be provided as a linear recess connecting sides of the molded part and the sensing portion.

The at least one guide portion may be provided as a recess having a depth increasing in a direction toward the sensing portion.

A bottom surface of the at least one guide portion may a staircase shape sloped toward the sensing portion.

The at least one guide portion may be disposed in four directions, having the sensing portion in a center thereof.

The at least one guide portion may be disposed in a radial manner, having the sensing portion in a center thereof.

A width of the at least one guide portion may be increased toward the sensing portion.

A width of the at least one guide portion may be decreased toward the sensing portion.

A width of the at least one guide portion may correspond to a diameter of the sensing portion.

The electronic element may be formed by stacking a sensor element on an application specific integrated circuit (ASIC).

The sensor element may include a temperature/humidity sensor.

According to another aspect of the present disclosure, a sensor package may include: a sensor element; and a molded part encapsulating the sensor element while allowing the sensor element to be partially exposed, wherein the molded part may include a recess-type guide portion traversing one surface of the molded part by way of the exposed portion of the sensor element.

The guide portion may be provided as a recess having a depth increasing in a direction toward the exposed portion of the sensor element.

According to another aspect of the present disclosure, a portable terminal may include: a sensor package including a molded part encapsulating a sensor element while allowing the sensor element to be partially exposed, the molded part including at least one guide portion traversing one surface of the molded part by way of the exposed portion of the sensor element; a board allowing the sensor package to be mounted thereon; and a case accommodating the board and the sensor package therein and having at least one fluid inlet.

The sensor package may be mounted on the board such that the at least one guide portion is disposed in a direction in which the exposed portion of the sensor element and the fluid inlet are aligned.

The at least one guide portion may be provided as a recess having a depth increasing in a direction toward the exposed portion of the sensor element.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a perspective view schematically illustrating a sensor package according to an exemplary embodiment of the present disclosure;

FIG. 2A is a cross-sectional view taken along line A-A′ of FIG. 1;

FIG. 2B is a cross-sectional view taken along line B-B′ of FIG. 1;

FIG. 3A is an enlarged cross-sectional view of a sensing portion and a guide portion of FIG. 2A;

FIG. 3B is an enlarged cross-sectional view in which the guide portion of FIG. 3A is omitted;

FIG. 4 is a perspective view schematically illustrating a sensor package according to another exemplary embodiment of the present disclosure;

FIG. 5 is a cross-sectional view taken along line B-B′ of FIG. 4;

FIGS. 6 through 8 are cross-sectional views schematically illustrating a sensor package according to another exemplary embodiment of the present disclosure;

FIGS. 9 through 11 are perspective views schematically illustrating a sensor package according to another exemplary embodiment of the present disclosure;

FIG. 12 is a cross-sectional view schematically illustrating a portable terminal having a sensor package according to an exemplary embodiment of the present disclosure; and

FIGS. 13 and 14 are graphs illustrating measurement data according to an exemplary embodiment of the present disclosure.

### DETAILED DESCRIPTION

Hereinafter, embodiments of the present disclosure will be described in detail with reference to the accompanying drawings.

The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art.

In the drawings, the shapes and dimensions of elements may be exaggerated for clarity, and the same reference numerals will be used throughout to designate the same or like elements.

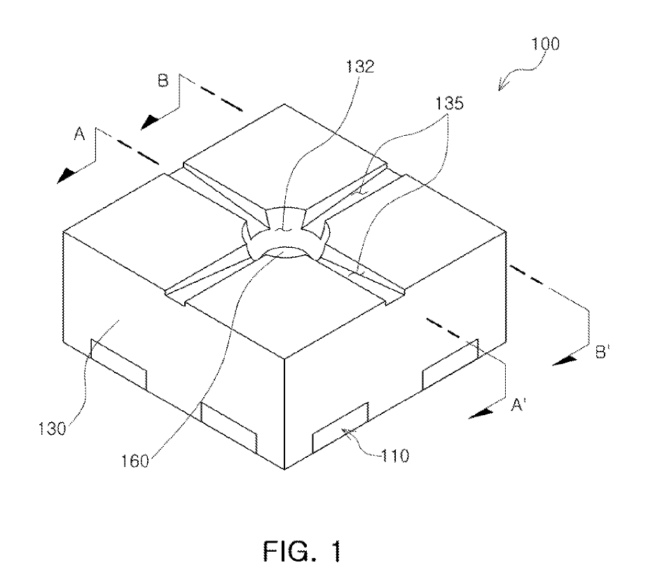

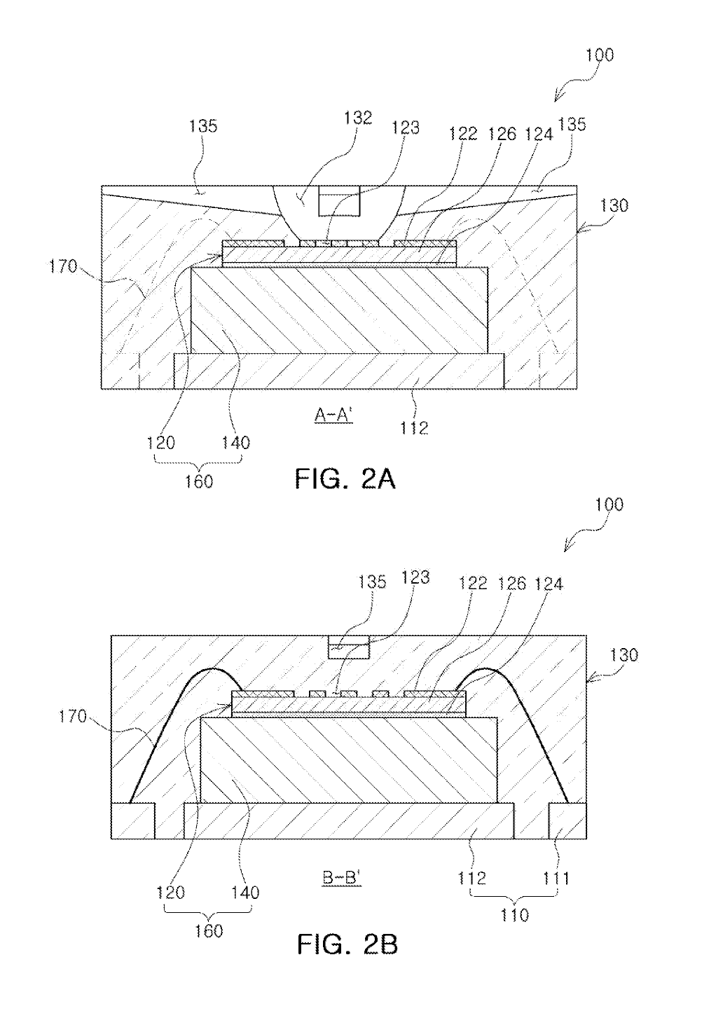

FIG. 1 is a perspective view schematically illustrating a sensor package according to an exemplary embodiment of the present disclosure, FIG. 2A is a cross-sectional view taken along line A-A′ of FIG. 1, and FIG. 2B is a cross-sectional view taken along line B-B′ of FIG. 1.

Referring to FIGS. 1 through 2B, a sensor package 100 according to the present exemplary embodiment may include a lead frame 110, at least one electronic element 160, and a molded part 130. The electronic element 160 may include a sensor element 120, a semiconductor element 140, and various passive and active elements required for operating the sensor element 120. The sensor package 100 may be a sensor package installed in a portable terminal to measure a temperature and humidity.

Various lead frames well known in the art may be used as the lead frame 110.

The lead frame 110 may serve as an external connection terminal allowing the electronic elements 160 to be electrically connected to the exterior. Also, the lead frame 110 may also serve as a board on which the electronic elements 160 are mounted.

The lead frame 110 may be formed of a metal such as copper (Cu) and may include a terminal part 111 electrically connected to the electronic elements 160 and a die pad 112 on which the electronic elements 160 are mounted.

The terminal part 111 may be electrically connected to the electronic elements 160 through a bonding wire 170. The terminal part 111 may serve as an external connection terminal, and to this end, the terminal part 111 may be electrically insulated from the die pad 112. However, the present disclosure is not limited thereto and the terminal part 111 may be electrically connected to the die pad 112, for grounding, or the like, as needed.

At least one electronic element 160 may be mounted on the die pad 112 of the lead frame 110. In FIG. 2A, it is illustrated that only a single electronic element 160 is mounted, but the present disclosure is not limited thereto and a larger number of electronic elements may be mounted as needed. The electronic elements may include both passive elements and active elements.

Meanwhile, in the present exemplary embodiment, the sensor package 100 including the lead frame 110 is taken as an example, but the present disclosure is not limited thereto. Namely, a board may be used instead of the lead frame 110. In this case, various boards such as a ceramic board, a printed circuit board (PCB), a flexible board, a glass board, and the like, may be used as the board. Also, a wiring pattern may be formed on at least one of surfaces of the board to electrically connect electrode pads allowing for the sensor element 120 or the semiconductor element 140 to be mounted thereon.

The sensor element 120 may be an element having a temperature-humidity sensor.

The sensor element 120 may include an upper electrode 122, a lower electrode 124, and an insulating layer 126 interposed between the upper electrode 122 and the lower electrode. Here, the insulating layer 126 may be formed of a polymer easily absorbing and discharging moisture to sense a temperature and humidity.

In the sensor element 120 according to the present exemplary embodiment, capacitance formed between the both electrodes is changed according to an amount of moisture, and it is converted to measure relative humidity. Thus, at least one through hole 123 may be formed in the upper electrode 122 to allow moisture to easily permeate into the insulating layer 126. Also, instead of the through hole 123, the upper electrode 122 may be formed of a porous material.

The sensor element 120 according to the present exemplary embodiment may be stacked on the semiconductor element 140 to format least one electronic element 160. Namely, the sensor element 120 and the semiconductor element 140 may be configured as a single element.

The semiconductor element 140 may be an application-specific integrated circuit (ASIC). However, the configuration of the present disclosure is not limited thereto and the semiconductor element 140 may include any general elements.

The semiconductor element 140 and the sensor element 120 may be sequentially stacked during a manufacturing process to form a single integrated element.

However, the present disclosure is not limited thereto and may be variously modified such that the semiconductor element 140 and the sensor element 120 are separately manufactured, and are stacked and electrically connected during a process of manufacturing the sensor package 100.

The electronic element 160 configured as described above may be electrically connected to the terminal part 111 of the lead frame 110 through the bonding wire 170. In this case, one end of the bonding wire 170 may be bonded to an upper surface of the sensor element 120 or an upper surface of the semiconductor element 140. Thus, the uppermost portion, a vertex, of the bonding wire 170 may be positioned to be higher than the upper surface of the sensor element 120.

The molded part 130 may seal the elements mounted on the lead frame 110. Also, the molded part 130 may fill spaces between the elements to prevent occurrence of an electrical short-circuit and safely protect the elements from external impacts.

The molded part 130 may be formed of an insulating material including a resin material such as epoxy molding compound (EMC).

In the present exemplary embodiment, the molded part 130 may be formed to cover the entirety of one surface of the lead frame 110. Also, the molded part 130 may be formed as having an overall rectangular parallelepiped shape corresponding to the shape of the lead frame 110.

Meanwhile, according to the present exemplary embodiment, the case in which all the elements mounted on the lead frame 110 are embedded within the molded part 130 is taken as an example. However, the present disclosure is not limited thereto and may be variously modified. For example, at least a portion of the elements may be exposed outside the molded part 130.

Also, in the present exemplary embodiment, a sensing portion 132 and at least one guide portion 135 may be formed in the molded part 130.

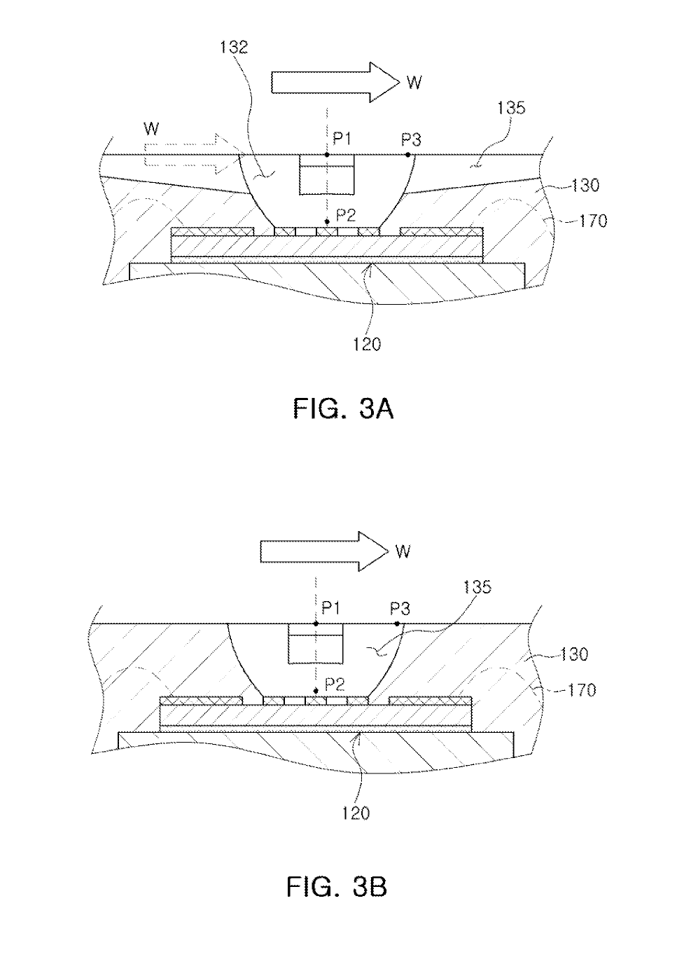

FIG. 3A is an enlarged cross-sectional view of a sensing portion and a guide portion of FIG. 2A, and FIG. 3B is an enlarged cross-sectional view in which the guide portion of FIG. 3A is omitted and only the sensing portion is formed.

Referring to FIGS. 3A and 3B, the sensing portion 132 may be formed to penetrate through the molded part 30, and one surface of the sensing portion may be disposed to close one end of the through hole. Thus, the sensing portion 132 may be formed as a recess in which the sensor element 120 forms a bottom surface.

A sectional area of the sensing portion 132 may be reduced toward one end thereof to allow a fluid (for example, air) to flow smoothly. Namely, a diameter of the sensing portion 130 may be increased upwardly. However, the present disclosure is not limited thereto and the sensing portion 132 may be formed as a hole having various shapes as needed.

The guide portion 135 may be formed as a recess connected to the sensing portion 132 and may be a passage guiding a fluid toward the sensing portion 132. Thus, the guide portion 135 may be formed as a linear recess connecting the sensing portion 132 and the side of the molded part 130.

In particular, the guide portion 135 may be formed as a recess of which a depth is increased toward the sensing portion 132. Thus, a bottom surface of the guide portion 135 may be formed as a sloped surface such that the depth is increased toward the sensing portion 132.

Also, in the present exemplary embodiment, the guide portion 135 is formed as an angular recess having side walls and a bottom surface. However, the present disclosure is not limited thereto and may be variously modified. For example, the lateral surfaces and the bottom surface of the guide portion 135 may be formed as continuous curved surfaces like a U shape, or may be formed to have a cross-section in a V shape without a bottom surface.

The guide portion 135 may be disposed between the bonding wires 170. If the guide portion 135 is disposed above vertices of the bonding wires 170, it may be difficult to form the guide portion 135 to be deeper, which may result in an increase in an overall height of the sensor package 100.

Thus, in the present exemplary embodiment, the guide portions 135 may be disposed between the bonding wires 170. When the guide portions 135 are formed as described above, a height of the molded part 130 may be minimized. However, the present disclosure is not limited thereto. For example, when the bonding wires 170 are disposed very densely, the guide portions 135 may be disposed above the bonding wires 170.

In the above-described configuration of the sensor package 100 according to the present exemplary embodiment, the sensor element 120 and the lead frame 110 are electrically connected through the bonding wires 170. Since the vertices of the bonding wires 170 are positioned above the sensor element 120, the molded part 130 encapsulating the bonding wires 170 may be formed such that an upper surface thereof is spaced apart from an upper portion of the sensor element 120 at a predetermined distance.

The sensor element 120 may be exposed outwardly through the sensing portion 132 as a through hole formed in the molded part 130.

Here, as illustrated in FIG. 3B, when the sensor package 100 has only the sensing portion 132, a fluid (hereinafter, referred to as ‘air’) filling the sensing portion 132 is enclosed within the sensing portion 132, and thus, the air may not easily flow.

Namely, since the interior of the sensing portion 32 is filled with the air, it is difficult for the air W flowing outside of the molded part 130 to be easily introduced to the interior of the sensing portion 132, and accordingly, the sensor element 120 may not be able to accurately detect a temperature and humidity.

Also, in this case, the ambient air W may flow only outside the molded part 130, so it takes a relatively long period of time for the ambient air W to spread into the sensing portion 132 and come into contact with the sensor element 120. Thus, it may take a relatively long period of time to sense a temperature and humidity.

For this reason, the sensing package according to the present exemplary embodiment includes at least one guide portion 135 as illustrated in FIG. 3A.

The guide portion 135 may be formed as a recess in the upper surface of the molded part 130 to guide the ambient air W to the sensing portion 132.

The guide portion 135 according to the present exemplary embodiment is formed to have a linear shape traversing the entirety of the upper surface of the molded part 130. Thus, the ambient air W may flow along the guide portion 135, while traversing the molded part 130.

During this process, internal pressure of the sensing portion 132 is lowered due to the air flow within the guide portion 135, allowing the air enclosed in the sensing portion 132 to be easily introduced to the guide portion, to cause the air enclosed in the sensing portion 132 to flow. Accordingly, the ambient air W may easily come into contact with the sensor element 120.

Also, since the guide portion 135 is connected to the sensing portion 132, the ambient air W flowing along the guide portion 135 may move, while partially passing through the interior (namely, the upper end portion) of the sensing portion 132.

Accordingly, a distance between the ambient air W and the sensor element 120 is minimized, and thus, a time during which the ambient air W spreads within the sensing portion 132 may also be minimized. Thus, a temperature and humidity may be rapidly sensed.

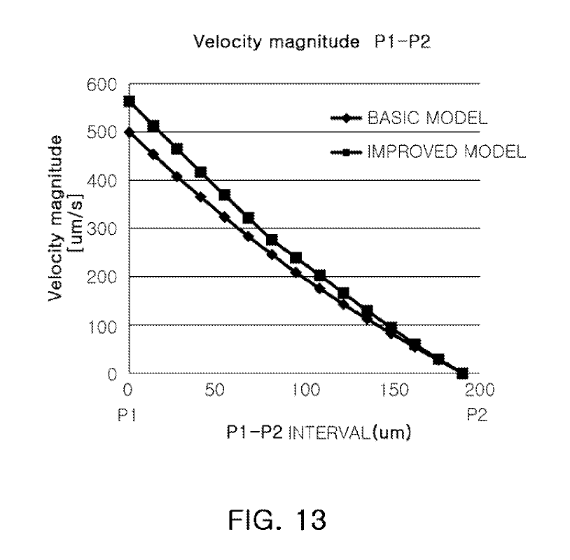

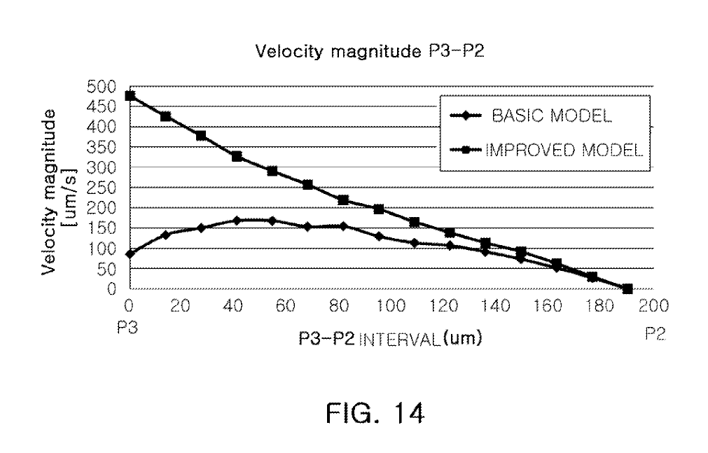

FIGS. 13 and 14 are graphs illustrating measurement data according to an exemplary embodiment of the present disclosure. Here, FIG. 13 is a graph illustrating a velocity magnitude measured at P1-P2 of FIGS. 3A and 3B, and FIG. 14 is a graph illustrating a velocity magnitude measured at P3-P2 of FIGS. 3A and 3B. Also, an improved model represents the structure illustrated in FIG. 3A, and a basic model represents the structure illustrated in FIG. 3B.

Here, the measurement was performed by setting a velocity of ambient air to 0.001 m/s.

First, referring to FIG. 13, it can be seen that, at P2, velocity magnitudes of both the improved model and the basic model are 0, while, at P1, the improved model has a velocity magnitude higher by approximately 10% than that of the basic model.

Also, referring to FIG. 14, it can be seen that, velocity magnitudes are significantly different at P3. Also, even in regions close to P2, the improved model has an increased velocity magnitude, relative to the existing model.

Thus, since the sensor package 100 according to the present exemplary embodiment has the guide portion 135, a velocity magnitude, namely, an air flow, at the sensing point of the sensor element 120 may be effectively increased. Thus, since the sensor element 120 quickly comes into contact with ambient air, a temperature and humidity may be accurately and promptly measured.

Meanwhile, the sensor package 100 according to the present disclosure is not limited to the foregoing exemplary embodiment and may be variously modified.

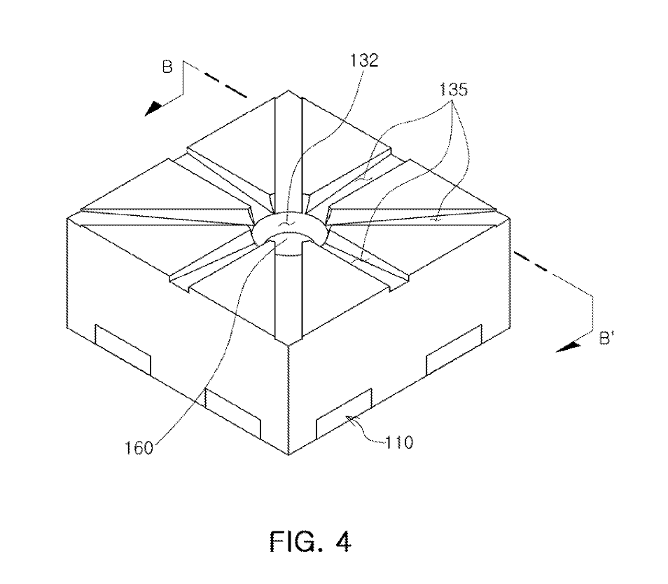

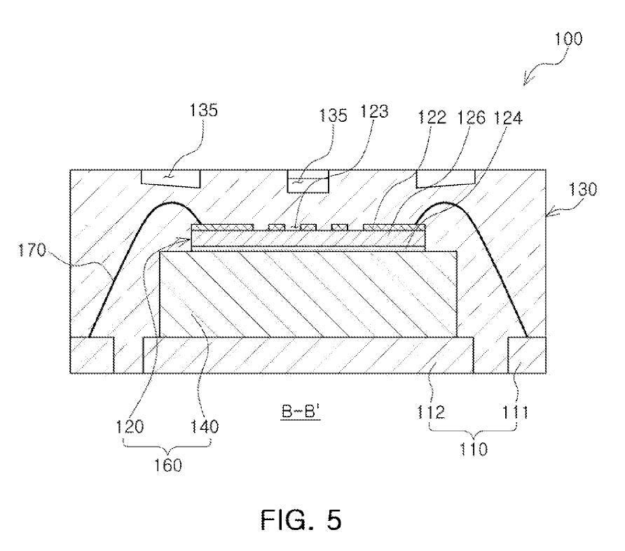

FIG. 4 is a perspective view schematically illustrating a sensor package according to another exemplary embodiment of the present disclosure, and FIG. 5 is a cross-sectional view taken along line B-B′ of FIG. 4.

Referring to FIGS. 4 and 5, in a sensor package according to the present exemplary embodiment, guide portions 135 are formed in a radial manner, having a sensing portion 132 in a center thereof. Namely, in addition to the guide portions according to the former exemplary embodiment, additional guide portions 135 are further provided in a diagonal direction of the molded part 130.

In this manner, in the sensor package according to the present exemplary embodiment, the guide portions 135 may be added in various forms. Also, the guide portions 135 may be formed in various directions as in the present exemplary embodiment, but are not limited thereto. The guide portions 135 may be variously modified. For example, the guide portions may be formed in only one direction to correspond to an air flow.

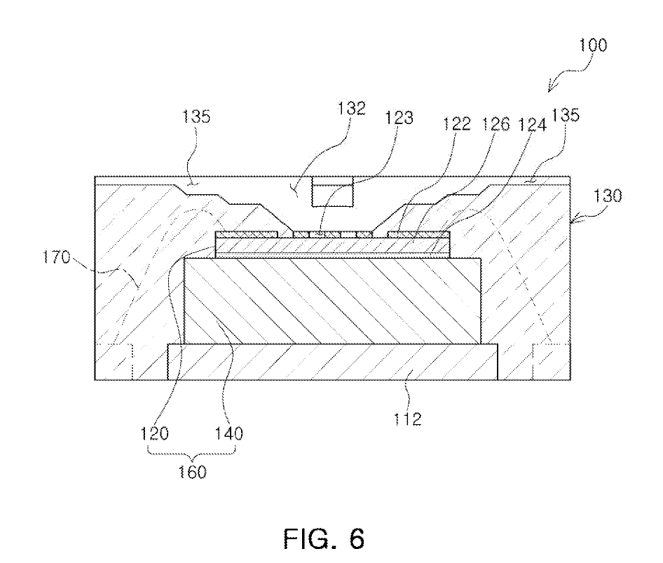

FIGS. 6 through 8 are cross-sectional views schematically illustrating a sensor package according to another exemplary embodiment of the present disclosure, in which respective cross-sections correspond to those taken along line A-A′ in FIG. 1.

Referring to FIG. 6, in the sensor package according to the present exemplary embodiment, a bottom surface of a guide portion 135 has a staircase shape, having at least one step.

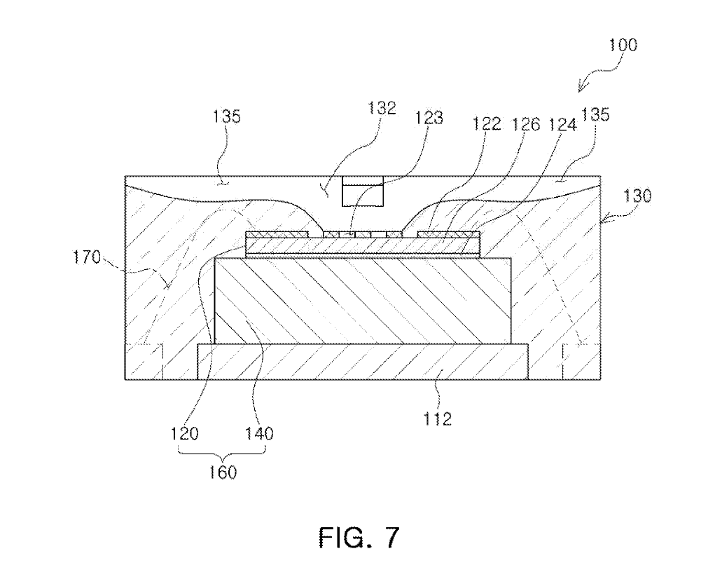

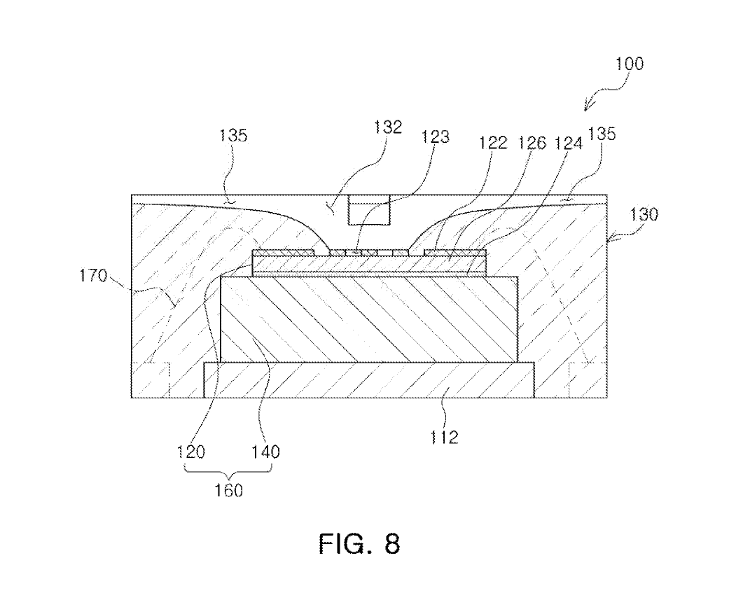

Also, FIGS. 7 and 8 illustrate that bottom surfaces of the guide portions 135 of the sensor packages are formed to have a curved shape or an arc shape. Here, FIGS. 7 and 8 illustrate that the curved surfaces are formed in opposite directions.

In these cases, the sensing portion 132 and the guide portion 35 may be formed as a continuous recess without a clear demarcation.

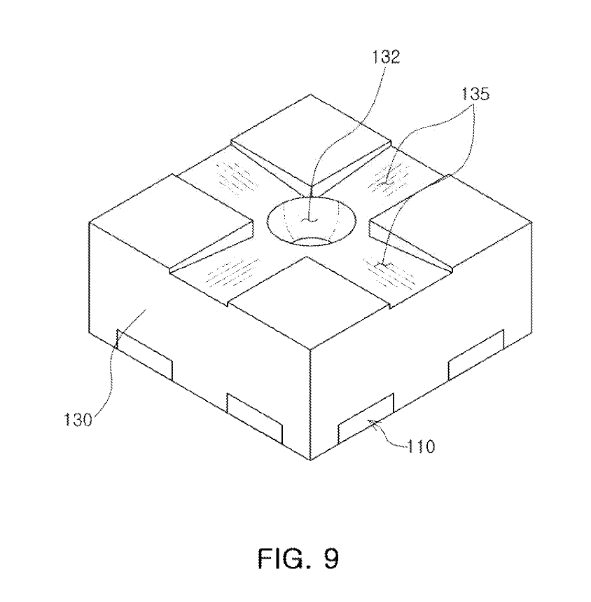

FIGS. 9 through 11 are perspective views schematically illustrating a sensor package according to another exemplary embodiment of the present disclosure.

FIG. 9 illustrates an example in which a guide portion 135 has a large width. Here, the width of the guide portion 135 may correspond to a diameter of the sensing portion 132. However, the present disclosure is not limited thereto and the guide portion 1345 may have a width larger than the diameter of the sensing portion 132.

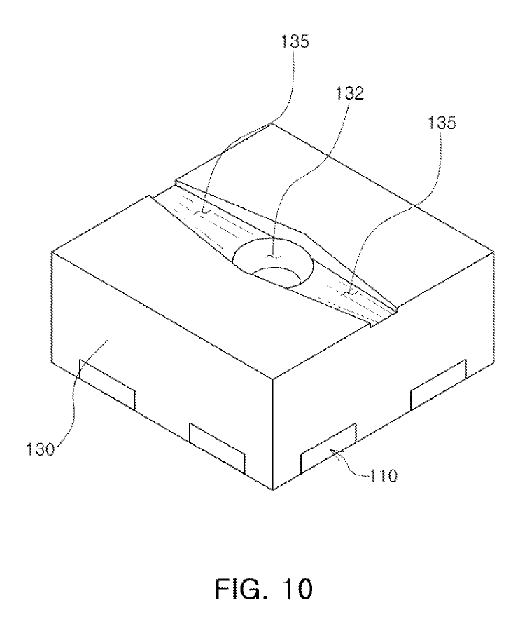

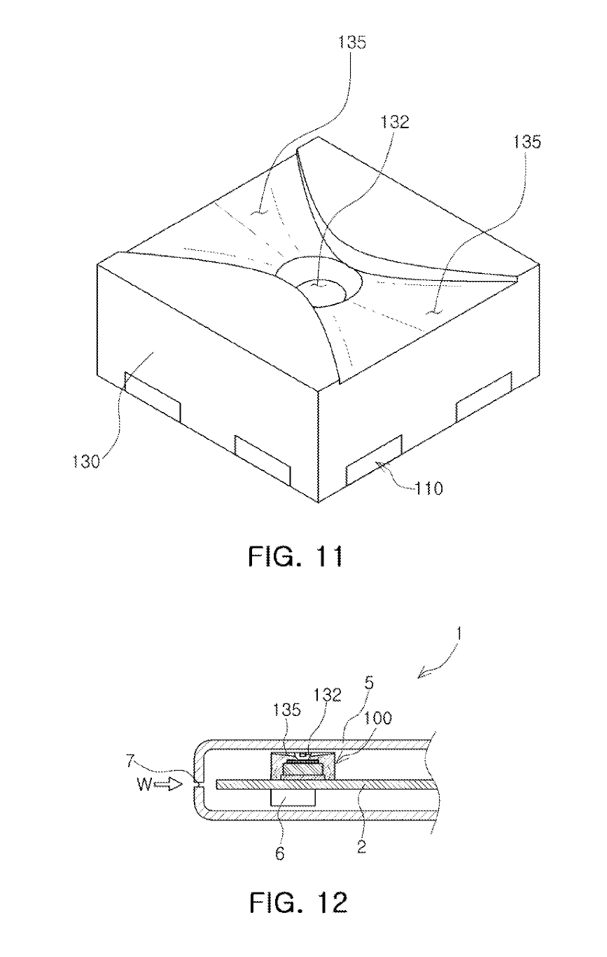

FIGS. 10 and 11 illustrate examples in which guide portions 135 are formed to have a width which is not equal but different in positions.

In the case of FIG. 10, the width of the guide portion 135 is increased toward the sensing portion 132, and in the case of FIG. 11, the width of the guide portion 135 is increased toward sides of the molded part 130.

In this manner, the guide portion 135 may be configured to have various forms in the sensor package 100 according to the present exemplary embodiment.

FIG. 12 is a cross-sectional view schematically illustrating a portable terminal having a sensor package according to an exemplary embodiment of the present disclosure.

Referring to FIG. 12, a portable terminal 1 according to the present exemplary embodiment may include a case 5, a board 2, and electronic components mounted on the board 2. Here, the electronic components may include the aforementioned sensor package 100 and a microphone element 6.

The case 5 forms the exterior of the portable terminal 1 and protects the components such as the board 2, the sensor package 100, and the like.

The case 5 has at least one fluid inlet 7. The inlet 7 may be used as a passage allowing a user voice to be introduced therethrough when the portable terminal 1 is used for the purpose of call communication. Also, the inlet 7 may be used as a passage allowing ambient air W to be sensed by the sensor package 100 to be introduced therethrough.

The board 2 may be fixedly disposed within the case 5, and the microphone element 6 may be mounted on at least one surface thereof.

In the present exemplary embodiment, the sensor package 100 is mounted on one surface of the board 2, and the microphone element 6 is mounted on the other surface thereof. However, the present disclosure is not limited thereto, and both of the foregoing components 100 and 6 may be mounted on any one surface of the board 2 as needed.

Also, in the portable terminal 1 according to the present exemplary embodiment, the guide portion 135 of the sensor package 100 is disposed to face the inlet 7. Namely, the sensor package 100 may be mounted on the board 2 such that the guide portion 135 is disposed in a direction in which the inlet 7 and the sensing portion 132 are aligned. Accordingly, the ambient air introduced through the inlet 7 may easily flow to the sensing portion 13 along the guide portion 135.

In this manner, the mounting structure according to the present exemplary embodiment may be variously modified as long as the guide portion 135 is disposed to be aligned as mentioned above.

As set forth above, since a sensor package according to exemplary embodiments of the present disclosure has guide portions, a velocity magnitude, namely, an air flow, at a sensing point of a sensor element may be effectively increased. Thus, the sensor element may quickly come into contact with ambient air to accurately and promptly measure a temperature and humidity.

While exemplary embodiments have been shown and described above, it will be apparent to those skilled in the art that modifications and variations could be made without departing from the spirit and scope of the present disclosure as defined by the appended claims.

What is claimed is:

1. A sensor package comprising:
a terminal part;
at least one electronic element electrically connected to the terminal part through a bonding wire; and
a molded part encapsulating the bonding wire and the electronic element and including a sensing portion partially exposing the electronic element and at least one guide portion guiding an ambient fluid to the sensing portion.

2. The sensor package of claim 1, wherein the sensing portion has a through hole, and
one surface of the electronic element closes one end of the through hole.

3. The sensor package of claim 2, wherein the sensing portion has a cross-sectional area decreasing in a direction toward one end thereof.

4. The sensor package of claim 1, wherein the terminal part is provided as a lead frame.

5. The sensor package of claim 1, wherein the bonding wire is disposed to have a vertex positioned higher than the electronic element.

6. The sensor package of claim 1, wherein the at least one guide portion is provided as a linear recess connecting sides of the molded part and the sensing portion.

7. The sensor package of claim 6, wherein the at least one guide portion is provided as a recess having a depth increasing in a direction toward the sensing portion.

8. The sensor package of claim 7, wherein a bottom surface of the at least one guide portion has a staircase shape sloped toward the sensing portion.

9. The sensor package of claim 1, wherein the at least one guide portion is disposed in four directions, having the sensing portion in a center thereof.

10. The sensor package of claim 1, wherein the at least one guide portion is disposed in a radial manner, having the sensing portion in a center thereof.

11. The sensor package of claim 1, wherein a width of the at least one guide portion is increased toward the sensing portion.

12. The sensor package of claim 1, wherein a width of the at least one guide portion is decreased toward the sensing portion.

13. The sensor package of claim 1, wherein a width of the at least one guide portion corresponds to a diameter of the sensing portion.

14. The sensor package of claim 1, wherein the electronic element is formed by stacking a sensor element on an application specific integrated circuit (ASIC).

15. The sensor package of claim 14, wherein the sensor element includes a temperature/humidity sensor.

16. A sensor package comprising:
a sensor element; and
a molded part encapsulating the sensor element while allowing the sensor element to be partially exposed,
wherein the molded part includes a recess-type guide portion traversing one surface of the molded part byway of the exposed portion of the sensor element.

17. The sensor package of claim 16, wherein the guide portion is provided as a recess having a depth increasing in a direction toward the exposed portion of the sensor element.

18. A portable terminal comprising:
a sensor package including a molded part encapsulating a sensor element while allowing the sensor element to be partially exposed, the molded part including at least one guide portion traversing one surface of the molded part by way of the exposed portion of the sensor element;
a board allowing the sensor package to be mounted thereon; and
a case accommodating the board and the sensor package therein and having at least one fluid inlet.

19. The portable terminal of claim 18, wherein the sensor package is mounted on the board such that the at least one guide portion is disposed in a direction in which the exposed portion of the sensor element and the fluid inlet are aligned.

20. The portable terminal of claim 19, wherein the at least one guide portion is provided as a recess having a depth increasing in a direction toward the exposed portion of the sensor element.
